(19) United States
(12) Patent Application Publication
(10) Pub. No.: US 2026/0082531 A1
(43) Pub. Date: Mar. 19, 2026

(54) MEMORY DEVICES AND METHODS OF MANUFACTURING THEREOF

(71) Applicant: Taiwan Semiconductor Manufacturing Company, Ltd., Hsinchu (TW)

(72) Inventors: Yi-Hsin Nien, New Taipei City (TW); Chih-Yu Lin, Hsinchu City (TW); Hidehiro Fujiwara, Hsinchu City (TW); Yen-Huei Chen, Hsinchu City (TW)

(73) Assignee: Taiwan Semiconductor Manufacturing Company, Ltd., Hsinchu (TW)

(21) Appl. No.: 18/982,071

(22) Filed: Dec. 16, 2024

Related U.S. Application Data
(60) Provisional application No. 63/694,495, filed on Sep. 13, 2024.

(51) Int. Cl. H10B 10/00

(52) U.S. Cl. CPC H10B 10/12; H10B 10/18

(57) ABSTRACT

A memory circuit includes a first array including first memory cells, a second array located next to the first array along a first direction and including second memory cells, a first input/output located opposite the first array from the second array along the first direction, a second input/output located opposite the second array from the first array along the first direction, and a bit-line coupled to the first input/output, a transistor of a first one of the first memory cells, and a transistor of a first one of the second memory cells. The transistor of the first one of the first memory cells has a gate with a first length extending in a second direction perpendicular to the first direction, and the transistor of the first one of the second memory cells has a gate with a second length extending in the second direction and shorter than the second length.

### CROSS-REFERENCE TO RELATED APPLICATION

This application claims priority to and the benefit of U.S. Provisional Application No. 63/694,495, filed Sep. 13, 2024, entitled “Dual Side IO And Bl Twist On DP SRAM To Optimize Write Vmin Caused By LDE Effect,” which is incorporated herein by reference in its entirety for all purposes.

### BACKGROUND

The semiconductor integrated circuit (IC) industry has experienced exponential growth. As ICs continue to scale down, more devices are integrated into the single chip. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an example memory device (or circuit), in accordance with some embodiments.

FIG. 2 illustrates a circuit diagram of an example memory cell that can be included in the memory device of FIG. 1, in accordance with some embodiments.

FIG. 3 illustrates a block diagram of an example memory device (or circuit), in accordance with some embodiments.

FIG. 4 illustrates an example layout associated with an example memory device, in accordance with some embodiments.

FIG. 5 illustrates a block diagram of an example circuit that can be included in the memory device of FIG. 1, in accordance with some embodiments.

FIG. 6 illustrates an example plot associated with a memory device, in accordance with some embodiments.

FIG. 7 illustrates a flow chart of an example method for forming a memory device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In advanced memory technologies, such as Dual-Port Static Random Access Memory (DP SRAM), the presence of two ports enables simultaneous read and write operations, thereby enhancing data throughput and efficiency. However, layout dependent effects (LDEs) significantly impact the device performance, as variations in the physical layout can lead to inconsistencies in electrical characteristics, such as speed and stability. For example, LDE increases the threshold voltages of pass-gate transistors, which degrades the alpha ratio. This degradation results in a higher minimum write voltage (WVmin) and increases the minimum voltage gap between the two ports, compromising the reliable operation of the device. As device geometries shrink, understanding and mitigating LDE becomes increasingly important to ensure reliable operation and performance in high-density memory applications.

The present disclosure provides techniques for mitigating LDE. In some embodiments, the techniques include utilizing a dual-side input/output (I/O) circuit. In some embodiments, the techniques include utilizing a twist structure (e.g., bit lines) in the memory cell. These techniques help balance the WVmin and improve the far-side WVmin. In some embodiments, for arrays near a selected I/O, the bit line is connected to a short poly pass-gate transistor (e.g., which may exhibit a worse alpha ratio), while for arrays located farther from the selected I/O, the bit line connects to a long poly pass-gate transistor (e.g., which may exhibit a better alpha ratio) via the twist structure. Furthermore, the twist structure can be implemented not only in the middle of the array but also at other points, enhancing the overall design of the device macro.

The present disclosure provides various embodiments of a memory circuit. The memory circuit can include a first memory array including a plurality of first memory cells, a second memory array including a plurality of second memory cells, the second memory array physically located next to the first memory array along a first lateral direction, a first input/output (I/O) circuit physically located opposite the first memory array from the second memory array along the first lateral direction, a second I/O circuit physically located opposite the second memory array from the first memory array along the first lateral direction, and a first bit line operatively coupled at least to the first I/O circuit, a first pass-gate transistor of a first one of the first memory cells, and a first pass-gate transistor of a first one of the second memory cells. The first pass-gate transistor of the first one of the first memory cells has a gate structure with a first length extending in a second lateral direction perpendicular to the first lateral direction, and the first pass-gate transistor of the first one of the second memory cells has a gate structure with a second length extending in the second lateral direction, and wherein the first length is shorter than the second length.

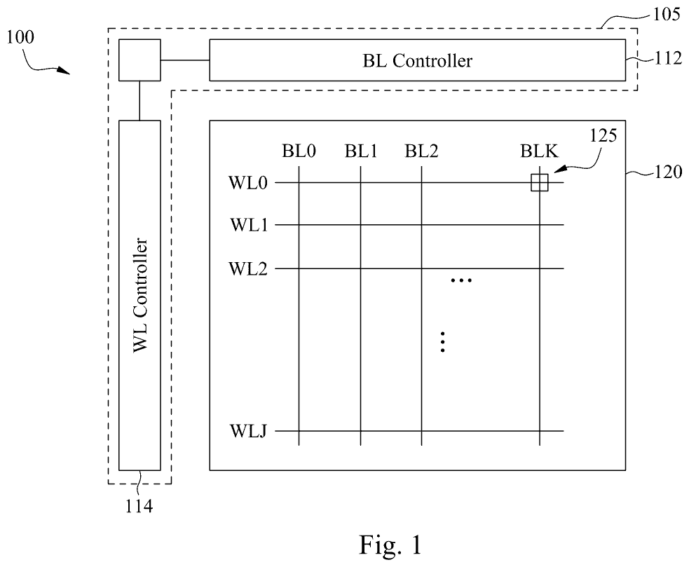

FIG. 1 illustrates a block diagram of an example memory device (or circuit) 100, in accordance with some embodiments. The memory device 100 includes a memory controller 105 and a memory array 120. In one aspect, the memory array 120 includes a plurality of storage circuits or memory cells 125. The memory array 120 further includes word lines WL₀, WL₁. . . WL_{J}, each extending in a direction (e.g., X-direction) and bit lines BL₀, BL₁. . . BL_{K}, each extending in another direction (e.g., Y-direction). The word lines WLs and the bit lines BLs may each be a conductive metal or conductive rail. In some embodiments, each memory cell 125 is coupled to a corresponding word line WL and a corresponding bit line BL, and can be operated according to voltages or currents through the corresponding word line WL and the corresponding bit line BL. In some embodiments, each bit line includes bit lines BL, BLB coupled to one or more memory cells 125 of a group of memory cells 125 disposed along the direction (e.g., Y-direction). The bit lines BL, BLB may receive and/or provide differential signals. In some embodiments, each bit line includes two bit lines BLs (e.g., A_BL, B_BL) and two bit lines BLBs (e.g., A_BLB, B_BLB). For example, in a DP SRAM, the bit lines A_BL and A_BLB may receive and/or provide differential signals through a first port (e.g., Port A), and the bit lines B_BL and B_BLB may receive and/or provide differential signals through a second port (e.g., Port B).

Each memory cell 125 may include a volatile memory cell, a non-volatile memory cell, or a combination of them. For example, each memory cell 125 is embodied as a static random access memory (SRAM) cell, a dual port (DP) SRAM cell, etc. However, it should be appreciated that the memory cell 125 can be implemented as any of various other non-volatile memory cells such as, for example, a resistive random access memory (RRAM) cell, a magnetoresistive random access memory (MRAM) cell, a phase-change random access memory (PCRAM) cell, an eFuse, an anti-fuse, etc., while remaining within the scope of the present disclosure. In some embodiments, the memory array 120 includes additional lines (e.g., select lines, reference lines, reference control lines, power rails, etc.).

The memory controller 105 is a hardware component that controls operations of the memory array 120. In some embodiments, the memory controller 105 includes a bit line (BL) controller 112, a word line (WL) controller 114, etc. The BL controller 112 and the WL controller 114 may be embodied as logic circuits, analog circuits, or a combination of them. In one configuration, the WL controller 114 can be a circuit that provides a voltage or current through one or more word lines WLs of the memory array 120. The BL controller 112 can be a circuit that provides or senses a voltage or current through one or more bit lines BLs of the memory array 120. The BL controller 112 may be coupled to bit lines BLs of the memory array 120, and the WL controller 114 may be coupled to word lines WLs of the memory array 120. In some embodiments, the BL controller 112 can include a dual-side input/output (I/O) circuit. For example, the BL controller 112 can include a first I/O circuit operatively coupled to a first memory array of the memory array 120, and include a second I/O circuit operatively coupled to a second memory array of the memory array 120. In some embodiments, the memory controller 105 includes more, fewer, or different components than shown in FIG. 1.

In some embodiments, the memory device 100 can include a first memory array (e.g., in the memory array 120) including a plurality of first memory cells, a second memory array (e.g., in the memory array 120) including a plurality of second memory cells, the second memory array physically located next to the first memory array along a first lateral direction (e.g., Y-direction), a first input/output (I/O) circuit physically located opposite the first memory array from the second memory array along the first lateral direction, a second I/O circuit physically located opposite the second memory array from the first memory array along the first lateral direction, and a first bit line operatively coupled at least to the first I/O circuit, a first pass-gate transistor of a first one of the first memory cells, and a first pass-gate transistor of a first one of the second memory cells. The first pass-gate transistor of the first one of the first memory cells has a gate structure with a first length extending in a second lateral direction perpendicular to the first lateral direction, and the first pass-gate transistor of the first one of the second memory cells has a gate structure with a second length extending in the second lateral direction, and wherein the first length is shorter than the second length.

In some examples, the memory device 100 can include a first memory cell of a first memory array (e.g., in the memory array 120), the first memory cell including a first pass-gate transistor, a second pass-gate transistor, a third pass-gate transistor, and a fourth pass-gate transistor operatively coupled to a first bit line, a second bit line, a third bit line complement to the first bit line, and a fourth bit line complement to the second bit line, respectively, and a second memory cell of a second memory array (e.g., in the memory array 120) physically disposed with respect to the first memory array along a first lateral direction, the second memory cell including a fifth pass-gate transistor, a sixth pass-gate transistor, a seventh pass-gate transistor, and an eighth pass-gate transistor operatively coupled to the second bit line, the first bit line, the fourth bit line, and the third bit line, respectively. The first bit line, the second bit line, the third bit line, and the fourth bit line each include at least a first metal track extending in the first lateral direction, a second metal track extending in a second lateral direction perpendicular to the first lateral direction, a third metal track extending in the first lateral direction, a fourth metal track extending in the second lateral direction, and fifth metal track extending in the first lateral direction, and wherein the first and fifth metal tracks are disposed in a first metallization layer, the second and fourth metal tracks are disposed in a second metallization layer, and the third metal track is disposed in a third metallization layer.

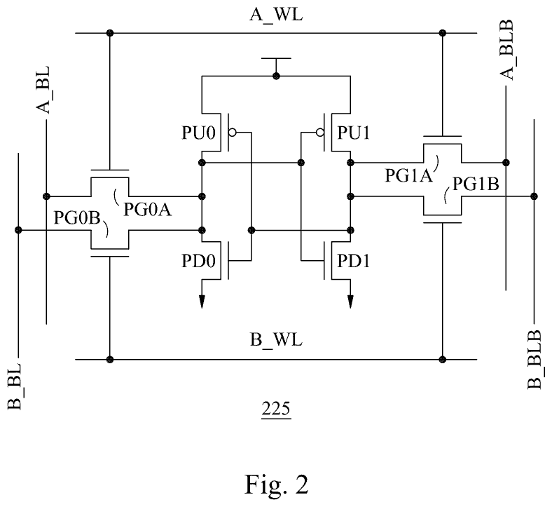

FIG. 2 illustrates a circuit diagram of an example memory cell 225 that can be included in the memory device 100 of FIG. 1, in accordance with some embodiments. In some embodiments, the memory cell 225 may be substantially similar to or incorporate features of the memory cell 125. The memory cell 225 can include a plurality of transistors (e.g., a pass-gate transistor PG0A, a pass-gate transistor PG0B, a pull-up transistor PU0, a pull-down transistor PD0, a pass-gate transistor PG1A, a pass-gate transistor PG1B, a pull-up transistor PU1, a pull-down transistor PD1, etc.). The memory cell 225 is shown to couple with at least one corresponding word line (e.g., A_WL, B_WL) and at least one corresponding bit line (e.g., A_BL, B_BL, A_BLB, B_BLB, etc.). It should be appreciated that the memory cell 225 of FIG. 2 is simplified for illustrative purposes, and thus, the memory cell 225 can be implemented as any of various other configurations while remaining within the scope of the present disclosure.

In some embodiments, the memory cell 225 can be a DP SRAM cell configured to store a bit of data with access through two ports (e.g., Port A, Port B (not shown)). The pull-up and pull-down transistors can form a cross-coupled latch configured to retain the data. For example, when the memory cell 225 stores a bit value (e.g., “1”), one side is held high by the pull-up transistor, while the opposite pull-down transistor pulls the other side low, retaining a state. The pass-gate transistors can enable access to the memory cell 225 through each port. Each port has its own set of bit lines (e.g., A_BL, A_BLB for Port A; B_BL, B_BLB for Port B) and word lines (e.g., A_WL for Port A; B_WL for Port B). During a write operation, activating the word line (either A_WL or B_WL) turns on the respective pass-gate transistors, connecting the storage nodes to the bit lines and allowing data to be written into the memory cell 225 by driving the bit lines to the desired values. For a read operation, the word line is similarly activated, allowing the stored data to be sensed through the bit lines without disturbing the state of the memory cell 225.

As disclosed herein, the memory devices (e.g., the memory cell 125, the memory cell 225, etc. thereof) can be configured to mitigate the unbalance minimum voltage caused by LDE. In some embodiments, the memory devices disclosed herein can include a dual-side input/output (I/O) circuit. In some embodiments, the memory devices disclosed herein can include a twist structure (e.g., for bit lines) in the memory cell. The figures and description below illustrate various examples of the memory devices with the dual-side I/O circuit and/or the twist structure. It should be noted that the figures and description below are non-limiting examples and can be implemented as any of various other configurations while remaining within the scope of the present disclosure.

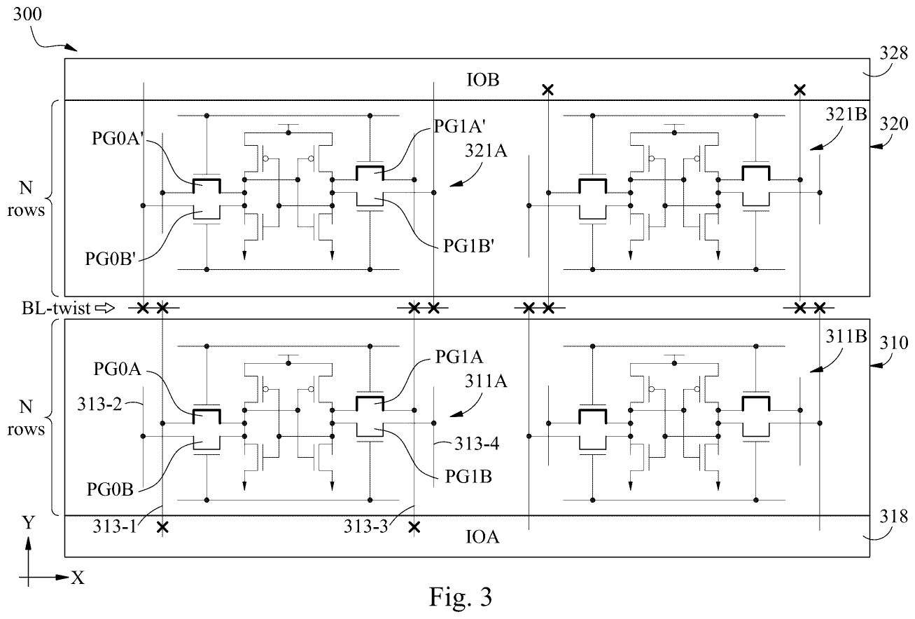

FIG. 3 illustrates a block diagram of an example memory device (or circuit) 300, in accordance with some embodiments. In some embodiments, the memory device 300 may be substantially similar to or incorporate features of the memory device 100. For example, the memory device 300 includes a memory array, which may be substantially similar to or incorporate features of the memory array 120. The memory device 300 includes a memory cell, which may be substantially similar to or incorporate features of the memory cell 125, the memory cell 225, etc. It should be appreciated that the memory device 300 of FIG. 3 is simplified for illustrative purposes, and thus, the memory device 300 can be implemented as any of various other configurations while remaining within the scope of the present disclosure.

The memory device 300 includes a first memory array 310 and a second memory array 320. The first memory array 310 includes a plurality of first memory cells (e.g., a memory cell 311A, a memory cell 311B, etc.). As shown in FIG. 3, the first memory array 310 can include N rows of the memory cells (e.g., the first memory cell 311A, the memory cell 311B, etc.). Although the first memory array 310 with N=1 is shown, N can be any integer number. The second memory array 320 includes a plurality of second memory cells (e.g., a memory cell 321A, a memory cell 321B, etc.). As shown in FIG. 3, the second memory array 320 can include N rows of the memory cells (e.g., the memory cell 321A, the memory cell 321B, etc.). Although the second memory array 320 with N=1 is shown, N can be any integer number. In some embodiments, the plurality of first memory cells in the first memory array 310 and the plurality of second memory cells in the second memory array 320 can each include a dual-port static random access memory (DP SRAM) cell, as illustrated in FIG. 2.

In some embodiments, as shown in FIG. 3, the second memory array 320 can be physically located next to the first memory array 310 along a first lateral direction (e.g., the Y-direction). In some embodiments, the second memory cell 321A of the second memory array 320 can be physically disposed with respect to the first memory array 310 along the first lateral direction. In some embodiments, the first memory array 310 can be operatively connected with the second memory array 320 through a BL-twist structure, which is discussed in greater detail below.

Each cell of the first memory array 310 and the second memory array 320 can include a plurality of transistors. In some embodiments, the first memory cell 311A of the first memory array 310 can include a first pass-gate transistor (e.g., PG0A of the first memory cell 311A), a second pass-gate transistor (e.g., PG0B of the first memory cell 311A), a third pass-gate transistor (e.g., PG1A of the first memory cell 311A), and a fourth pass-gate transistor (e.g., PG1B of the first memory cell 311A). The second memory cell 321A can include a fifth pass-gate transistor (e.g., PG0A′ of the second memory cell 321A), a sixth pass-gate transistor (e.g., PG0B′ of the second memory cell 321A), a seventh pass-gate transistor (e.g., PG1A′ of the second memory cell 321A), and an eighth pass-gate transistor (e.g., PG1B′ of the second memory cell 321A).

In some embodiments, the memory device 300 includes a first input/output (I/O) circuit 318. The first I/O circuit 318 can be physically located opposite the first memory array 310 from the second memory array 320 along the first lateral direction. The first I/O circuit 318 can be operatively coupled with the first memory array 310. In some embodiments, the memory device 300 includes a second I/O circuit 328. The second I/O circuit 328 can be physically located opposite the second memory array 320 from the first memory array 310 along the first lateral direction. The second I/O circuit 328 can be operatively coupled with the second memory array 320.

In some embodiments, the memory device 300 includes a first bit line 313-1. The first bit line 313-1 can be operatively coupled at least to the first I/O circuit 318, the first pass-gate transistor (e.g., PG0A of the first memory cell 311A), and the sixth pass-gate transistor (e.g., PG0B′ of the second memory cell 321A). In some embodiments, the memory device 300 includes a second bit line 313-2. The second bit line 313-2 can be operatively coupled at least to the second I/O circuit 328, the second pass-gate transistor (e.g., PG0B of the first memory cell 311A), and the fifth pass-gate transistor (e.g., PG0A′ of the second memory cell 321A). In some embodiments, the memory device 300 includes a third bit line 313-3 complement to the first bit line 313-1. In some embodiments, the memory device 300 includes a fourth bit line 313-4 complement to the second bit line 313-2. The first pass-gate transistor of the first memory cell 311A, the second pass-gate transistor of the first memory cell 311A, the third pass-gate transistor of the first memory cell 311A, and the fourth pass-gate transistor of the first memory cell 311A can be operatively coupled to the first bit line 313-1, the second bit line 313-2, the third bit line, and the fourth bit line, respectively. The fifth pass-gate transistor of the second memory cell 321A, the sixth pass-gate transistor of the second memory cell 321A, the seventh pass-gate transistor of the second memory cell 321A, and the eighth pass-gate transistor of the second memory cell 321A can be operatively coupled to the second bit line 313-2, the first bit line 313-1, the fourth bit line, and the third bit line, respectively. As shown in FIG. 3 (e.g., “BL-twist”) and described herein, the bit lines (e.g., the first bit line 313-1, the second bit line 313-2, etc.) can be configured to form a twist structure, while operatively coupling the first memory array 310 with the second memory array 320. As discussed in greater detail below, and shown in FIG. 3, the twist structure allows an I/O (e.g., the first I/O circuit 318) to connect a transistor (e.g., PG0A, PG1A, etc.) with a gate structure having a shorter length at the near end, and to connect a transistor (e.g., PG0B, PG1B, etc.) with a gate structure having a longer length at the far end.

In some embodiments, the first pass-gate transistor (e.g., PG0A of the first memory cell 311A) has a gate structure with a first length extending in a second lateral direction (e.g., the X-direction) perpendicular to the first lateral direction, and the sixth pass-gate transistor (e.g., PG0B′ of the second memory cell 321A) has a gate structure with a second length extending in the second lateral direction. In some embodiments, the first length can be shorter than the second length. In some embodiments, the fifth pass-gate transistor (e.g., PG0A′ of the second memory cell 321A) has a gate structure with the first length extending in the second lateral direction, and the second pass-gate transistor (e.g., PG0B of the first memory cell 311A) has a gate structure with the second length extending in the second lateral direction.

In some embodiments, each of the first memory array 310 and the second memory array 320 can include a plurality of rows (e.g., N>2), including a second one (not shown) of the memory cells of the first memory array 310 and a second one (not shown) of the memory cells of the second memory array 320. The second one of the memory cells of the first memory array 310 and the second one of the memory cells of the second memory array 320 can be arranged along the Y-axis. That is, in some embodiments, the first one and the second one of the memory cells of the first memory array 310 can be physically located with respect to each other along the first lateral direction (e.g., the Y-direction), and the first one and the second one of the memory cells of the second memory array 320 can be physically located with respect to each other along the first lateral direction (e.g., the Y-direction).

In some embodiments, the first bit line 313-1 can be operatively coupled further to a first pass-gate transistor of the second one of the memory cells of the first memory array 310, and a first pass-gate transistor of the second one of the memory cells of the second memory array 320. In some embodiments, the first pass-gate transistor of the second one of the memory cells of the first memory array 310 has a gate structure with the first length (e.g., the same as the gate structure of the fifth pass-gate transistor) extending in the second lateral direction, and the first pass-gate transistor of the second one of the memory cells of the second memory array 320 has a gate structure with the second length (e.g., the same as the gate structure of the second pass-gate transistor) extending in the second lateral direction.

As discussed above, in some embodiments, the first I/O circuit 318 can be operatively coupled with the first memory array 310, and the second I/O circuit 328 can be operatively coupled with the second memory array 320. In some embodiments, the first I/O circuit 318 can be operatively coupled to the first pass-gate transistor PG0A and the sixth transistor PG0B′ through the first bit line 313-1, and to the third pass-gate transistor PG1A and the eighth pass-gate transistor PG1B′ through the third bit line 313-3. In some embodiments, the second I/O circuit 328 can be operatively coupled to the fifth pass-gate transistor PG0A′ and the second pass-gate transistor PG0B through the second bit line 313-2, and to the seventh pass-gate transistor PG1A′ and the fourth pass-gate transistor PG1B through the fourth bit line 313-4.

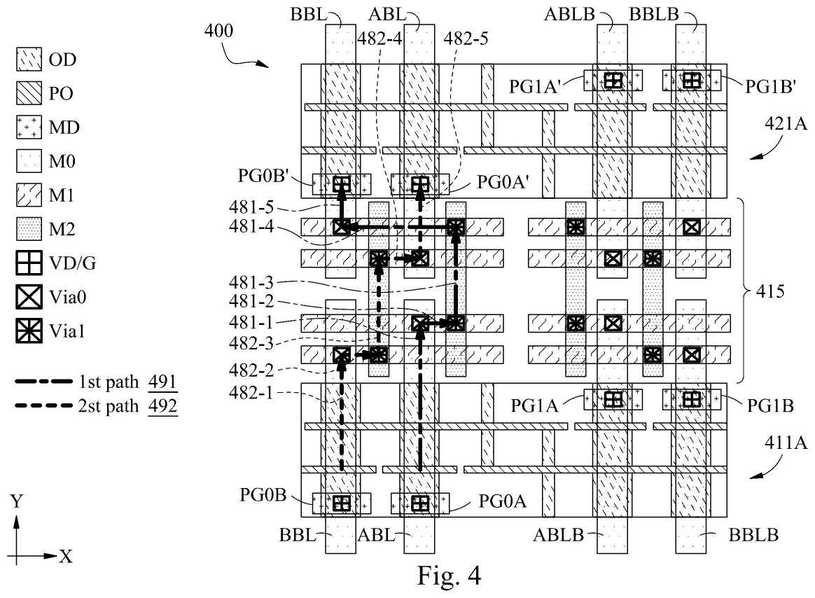

FIG. 4 illustrates an example layout associated with an example memory device (or circuit) 400, in accordance with some embodiments. In some embodiments, the memory device 400 may be substantially similar to or incorporate features of the memory device 100, the memory device 300, etc. In some embodiments, the layout of FIG. 4 may be of the memory device 100, the memory device 300, etc. It should be appreciated that the memory device 400 of FIG. 4 is simplified for illustrative purposes, and thus, can be implemented as any of various other configurations while remaining within the scope of the present disclosure.

The memory device 400 includes a first memory cell 411A, a second memory cell 421A, and a twist BL structure 415. In some embodiments, the first memory cell 411A may be of a first memory array of the memory device 400, and the second memory cell 421A may be of a second memory array of the memory device 400. In some embodiments, the first memory cell 411A includes a first pass-gate transistor PG0A, a second pass-gate transistor PG0B, a third pass-gate transistor PG1A, and a fourth pass-gate transistor PG1B. The second memory cell 421A includes a fifth pass-gate transistor PG0A′, a sixth pass-gate transistor PG0B′, a seventh pass-gate transistor PG1A′, and an eighth pass-gate transistor PG1B′. As discussed in greater detail below, the twist BL structure 415 can include a plurality of metal tracks to operatively couple the first memory cell 411A with the second memory cell 421A.

In some embodiments, the first pass-gate transistor PG0A, the second pass-gate transistor PG0B, the third pass-gate transistor PG1A, and the fourth pass-gate transistor PG1B can be operatively coupled to a first bit line (e.g., defining a first path 491 or a portion thereof (e.g., ABL)), a second bit line (e.g., defining a second path 492 or a portion thereof (e.g., BBL)), a third bit line (e.g., defining a third path (not shown) or a portion thereof (e.g., ABLB)) complement to the first bit line, and a fourth bit line (e.g., defining a fourth path (not shown) or a portion thereof (e.g., BBLB)) complement to the second bit line. In some embodiments, the fifth pass-gate transistor PG0A′, the sixth pass-gate transistor PG0B′, the seventh pass-gate transistor PG1A′, and the eighth pass-gate transistor PG1B′ can be operatively coupled to the second bit line (e.g., defining the second path 492 or a portion thereof (e.g., ABL)), the first bit line (e.g., defining the first path 491 or a portion thereof (e.g., BBL)), the fourth bit line (e.g., defining the fourth path (not shown) or a portion thereof (e.g., ABLB)), and the third bit line (e.g., defining the third path (not shown) or a portion thereof (e.g., BBLB)), respectively. In some embodiments, the first, third, fifth, and seventh pass-gate transistors can each have a gate structure with a first length extending in the second lateral direction, and the second, fourth, sixth, and eighth pass-gate transistors can each have a gate structure with a second length. In some embodiments, the first length is shorter than the second length.

In some embodiments, the first bit line can include at least a first metal track 481-1 extending in a first lateral direction (e.g., the Y-direction), a second metal track 481-2 extending in a second lateral direction (e.g., the X-direction), a third metal track 481-3 extending in the first lateral direction, a fourth metal track 481-4 extending in the second lateral direction, and a fifth metal track 481-5 extending in the first lateral direction. Likewise, the second bit line can include at least a sixth metal track 482-1 extending in the first lateral direction (e.g., the Y-direction), a seventh metal track 482-2 extending in the second lateral direction (e.g., the X-direction), an eighth metal track 482-3 extending in the first lateral direction, a ninth metal track 482-4 extending in the second lateral direction, and a tenth metal track 482-5 extending in the first lateral direction.

In some embodiments, the first metal track 481-1 and the fifth metal track 481-5 can be disposed in a first metallization layer (e.g., M0), the second metal track 481-2 and the fourth metal track 481-4 can be disposed in a second metallization layer (e.g., M1), and the third metal track 481-3 can be disposed in a third metallization layer (e.g., M2). Likewise, the sixth metal track 482-1 and the tenth metal track 482-5 can be disposed in the first metallization layer (e.g., M0), the seventh metal track 482-2 and the ninth metal track 482-4 can be disposed in the second metallization layer (e.g., M1), and the eighth metal track 482-3 can be disposed in the third metallization layer (e.g., M2). In some embodiments, the third metallization layer can be disposed over the first metallization layer. In some embodiments, the second metallization layer can be disposed over the first metallization layer. In some embodiments, the third metallization layer can be disposed over the second metallization layer. In some embodiments, as shown in FIG. 4, the second to fourth metal tracks can be interposed between the first memory array (e.g., including the first memory cell 411A) and the second memory array (e.g., including the second memory cell 421A) in the first lateral direction (e.g., the Y-direction).

As shown in FIG. 4, the twist BL structure 415 can include various structures to operatively couple metal tracks with each other and/or operatively couple metallization layers with each other. In some embodiments, the metallization layer M0 can be operatively coupled with the metallization layer M1 through one or more via structures Via0. The metallization layer M0 (and/or the metal tracks formed therein) can be operatively coupled with the metallization layer M1 (and/or the metal tracks formed therein) through one or more via structures Via0. The metallization layer M2 (and/or the metal tracks formed therein) can be operatively coupled with the metallization layer M3 (and/or the metal tracks formed therein) through one or more via structures Via1.

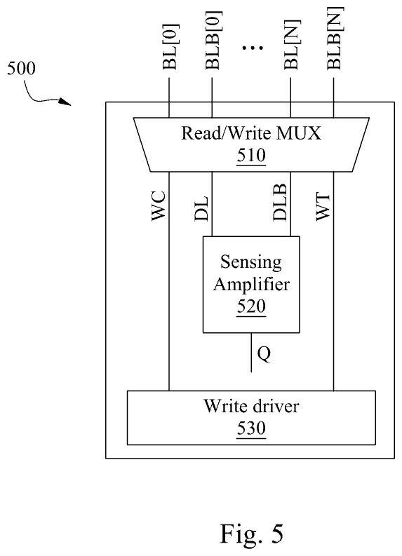

FIG. 5 illustrates a block diagram of an example circuit 500 that can be included in a memory device (or circuit), in accordance with some embodiments. In some embodiments, the circuit 500 can be included in the memory device 100, the memory device 300, the memory device 400, etc. In some embodiments, the circuit 500 can be an I/O circuit (e.g., the first I/O circuit 318, the second I/O circuit 328 of FIG. 3) of the memory device. It should be appreciated that the circuit 500 of FIG. 5 is simplified for illustrative purposes, and thus, can be implemented as any of various other configurations while remaining within the scope of the present disclosure.

In some embodiments, the circuit 500 can include an R/W MUX 510, a sensing amplifier 520, and a write driver 530. The circuit 500 can include or be operatively coupled to bit lines BL[0], BLB[0], . . . , BL[N], BLB[N], etc. In some embodiments, the bit lines BL[0] and BLB[0] can be operatively coupled to a first memory cell (e.g., the memory cell 311A). The bit lines BL[N] and BLB[N] can be operatively coupled to a second memory cell (e.g., the memory cell 311B). In some embodiments, the R/W MUX 510 can be configured to select bit lines during read and write operations. The sensing amplifier 520 can be configured to detect and amplify a voltage difference between the selected bit lines to read the stored data. The amplified signal Q can be sent to the write driver 530 to modify and/or reinforce data during the write operation. The word line controls WC, WT can be configured to control timing and operation of the circuit 500, allowing for precise control over the data access and modification processes.

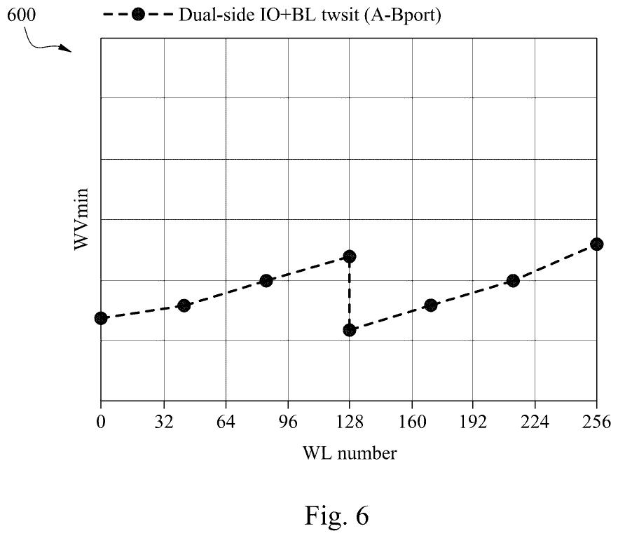

FIG. 6 illustrates an example plot 600 associated with a memory device (or circuit), in accordance with some embodiments. In some embodiments, the plot 600 may be associated with the memory device 100, the memory device 300, the memory device 400, etc. As shown, the plot 600 shows a WVmin as a function of a WL number. With a dual-side I/O circuit (e.g., the first I/O circuit 318, the second I/O circuit 328) and a twist BL structure (e.g., the twist BL structure 415), the WVmin can be balanced. For example, as shown in FIG. 6, a far-side WVmin (e.g., the WL number bigger than 128) can be reduced, thereby balancing the A-B port WVmin.

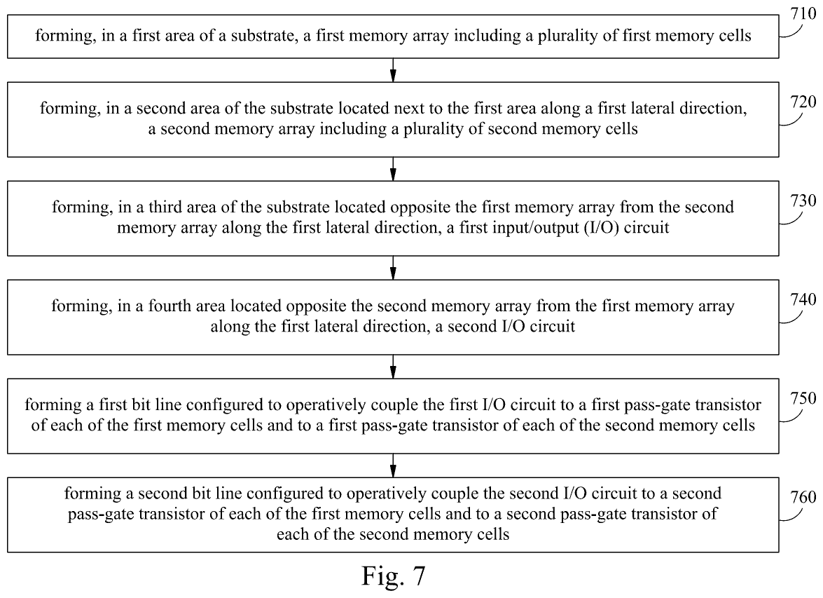

FIG. 7 illustrates a flow chart of an example method 700 for forming a memory device (or circuit), in accordance with some embodiments. In some embodiments, the method 700 can be performed to form a memory device based on the layout discussed with respect to FIG. 4, and thus, some of the references used above may be reused in the following discussion of the method 700. It is noted that the method 700 is merely an example and is not intended to limit the present disclosure. Accordingly, it is understood that additional operations may be provided before, during, and after the method 700 of FIG. 7, and that some other operations may only be briefly described herein.

In a brief overview, the method 700 can begin with operation 710 of forming, in a first area of a substrate, a first memory array including a plurality of first memory cells. The method 700 continues to operation 720 of forming, in a second area of the substrate located next to the first area along a first lateral direction, a second memory array including a plurality of second memory cells. The method 700 continues to operation 730 forming, in a third area of the substrate located opposite the first memory array from the second memory array along the first lateral direction, a first input/output (I/O) circuit. The method 700 continues to operation 740 of forming, in a fourth area located opposite the second memory array from the first memory array along the first lateral direction, a second I/O circuit. The method 700 continues to operation 750 of forming a first bit line configured to operatively couple the first I/O circuit to a first pass-gate transistor of each of the first memory cells and to a first pass-gate transistor of each of the second memory cells. The method 700 continues to operation 760 of forming a second bit line configured to operatively couple the second I/O circuit to a second pass-gate transistor of each of the first memory cells and to a second pass-gate transistor of each of the second memory cells.

At operation 710, in a first area of a substrate, a first memory array (e.g., the first memory array 310) including a plurality of first memory cells (e.g., the memory cell 311A, the memory cell 311B, etc.) can be formed. At operation 720, in a second area of the substrate located next to the first area along a first lateral direction (e.g., the Y-direction shown in FIG. 3), a second memory array (e.g., the second memory array 320) including a plurality of second memory cells (e.g., the memory cell 321A, the memory cell 321B, etc.) can be formed.

At operation 730, in a third area of the substrate located opposite the first memory array from the second memory array along the first lateral direction, a first input/output (I/O) circuit (e.g., the first I/O circuit 318) can be formed. At operation 740, in a fourth area located opposite the second memory array from the first memory array along the first lateral direction, a second I/O circuit (e.g., the second I/O circuit 328) can be formed.

At operation 750, a first bit line (e.g., the bit line 313-1) can be formed. The first bit line can be configured to operatively couple the first I/O circuit to a first pass-gate transistor (e.g., the first pass-gate transistor PG0A of FIG. 3) of each of the first memory cells and to a first pass-gate transistor (the sixth pass-gate transistor PG0B′ of FIG. 3) of each of the second memory cells. At operation 760, a second bit line (e.g., the bit line 313-2) can be formed. The second bit line can be configured to operatively couple the second I/O circuit to a second pass-gate transistor (e.g., the second pass-gate transistor PG0B of FIG. 3) of each of the first memory cells and to a second pass-gate transistor (e.g., the fifth pass-gate transistor PG0A′) of each of the second memory cells.

In some embodiments, the first pass-gate transistor of each of the first memory cells and the second pass-gate transistor of each of the second memory cells can each have a gate structure with a first length extending in a second lateral direction perpendicular to the first lateral direction. In some embodiments, the second pass-gate transistor of each of the first memory cells and the first pass-gate transistor of each of the second memory cells can each have a gate structure with a second length extending in the second lateral direction, and wherein the first length is shorter than the second length.

In some embodiments, in forming the first bit line, the method 700 can include forming a first metal track (e.g., the first metal track 481-1) extending in the first lateral direction and in a first one (e.g., the metallization layer M0) of a plurality of metallization layers over the substrate. The method 700 can include forming a second metal track (e.g., the second metal track 481-2) extending in the second lateral direction and in a second one (e.g., the metallization layer M1) of the plurality of metallization layers over the first metallization layer. The method 700 can include forming a third metal track (e.g., the third metal track 481-3) extending in the first lateral direction and in a third one (e.g., the metallization layer M2) of the plurality of metallization layers over the second metallization layer. The method 700 can include forming a fourth metal track (e.g., the fourth metal track 481-4) extending in the second lateral direction and in the second metallization layer. The method 700 can include forming a fifth metal track (e.g., the fifth metal track 481-5) extending in the first lateral direction and in the first metallization layer.

In some embodiments, in forming the second bit line, the method 700 can include forming a sixth metal track (e.g., the sixth metal track 482-1) extending in the first lateral direction and in the first metallization layer. The method can include forming a seventh metal track (e.g., seventh metal track 482-2) extending in the second lateral direction and in the second metallization layer. The method 700 can include forming an eighth metal track (e.g., the eighth metal track 482-3) extending in the first lateral direction and in the third metallization layer. The method 700 can include forming a ninth metal track (e.g., the ninth metal track 482-4) extending in the second lateral direction and in the second metallization layer. The method 700 can include forming a tenth metal track (e.g., the tenth metal track 482-5) extending in the first lateral direction and in the first metallization layer.

In one aspect of the present disclosure, a memory circuit is disclosed. The memory circuit includes a first memory array including first memory cells, a second memory array including second memory cells, the second memory array physically located next to the first memory array along a first lateral direction, a first input/output (I/O) circuit physically located opposite the first memory array from the second memory array along the first lateral direction, a second I/O circuit physically located opposite the second memory array from the first memory array along the first lateral direction, and a first bit line operatively coupled at least to the first I/O circuit, a first pass-gate transistor of a first one of the first memory cells, and a first pass-gate transistor of a first one of the second memory cells. The first pass-gate transistor of the first one of the first memory cells has a gate structure with a first length extending in a second lateral direction perpendicular to the first lateral direction, and the first pass-gate transistor of the first one of the second memory cells has a gate structure with a second length extending in the second lateral direction. The first length is shorter than the second length.

In another aspect of the present disclosure, a memory circuit is disclosed. The memory circuit includes a first memory cell of a first memory array, the first memory cell including a first pass-gate transistor, a second pass-gate transistor, a third pass-gate transistor, and a fourth pass-gate transistor operatively coupled to a first bit line, a second bit line, a third bit line complement to the first bit line, and a fourth bit line complement to the second bit line, respectively, and a second memory cell of a second memory array physically disposed with respect to the first memory array along a first lateral direction, the second memory cell including a fifth pass-gate transistor, a sixth pass-gate transistor, a seventh pass-gate transistor, and an eighth pass-gate transistor operatively coupled to the second bit line, the first bit line, the fourth bit line, and the third bit line, respectively. The first bit line, the second bit line, the third bit line, and the fourth bit line each include at least a first metal track extending in the first lateral direction, a second metal track extending in a second lateral direction perpendicular to the first lateral direction, a third metal track extending in the first lateral direction, a fourth metal track extending in the second lateral direction, and fifth metal track extending in the first lateral direction. The first and fifth metal tracks are disposed in a first metallization layer, the second and fourth metal tracks are disposed in a second metallization layer, and the third metal track is disposed in a third metallization layer.

In yet another aspect of the present disclosure, a method for fabricating memory devices is disclosed. The method includes forming, in a first area of a substrate, a first memory array including a plurality of first memory cells, forming, in a second area of the substrate located next to the first area along a first lateral direction, a second memory array including a plurality of second memory cells, forming, in a third area of the substrate located opposite the first memory array from the second memory array along the first lateral direction, a first input/output (I/O) circuit, forming, in a fourth area located opposite the second memory array from the first memory array along the first lateral direction, a second I/O circuit, forming a first bit line configured to operatively couple the first I/O circuit to a first pass-gate transistor of each of the first memory cells and to a first pass-gate transistor of each of the second memory cells, and forming a second bit line configured to operatively couple the second I/O circuit to a second pass-gate transistor of each of the first memory cells and to a second pass-gate transistor of each of the second memory cells. The first pass-gate transistor of each of the first memory cells and the second pass-gate transistor of each of the second memory cells each have a gate structure with a first length extending in a second lateral direction perpendicular to the first lateral direction, and the second pass-gate transistor of each of the first memory cells and the first pass-gate transistor of each of the second memory cells each have a gate structure with a second length extending in the second lateral direction. The first length is shorter than the second length.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory circuit, comprising:
a first memory array comprising a plurality of first memory cells;
a second memory array comprising a plurality of second memory cells, the second memory array physically located next to the first memory array along a first lateral direction;
a first input/output (I/O) circuit physically located opposite the first memory array from the second memory array along the first lateral direction;
a second I/O circuit physically located opposite the second memory array from the first memory array along the first lateral direction; and
a first bit line operatively coupled at least to the first I/O circuit, a first pass-gate transistor of a first one of the first memory cells, and a first pass-gate transistor of a first one of the second memory cells;
wherein the first pass-gate transistor of the first one of the first memory cells has a gate structure with a first length extending in a second lateral direction perpendicular to the first lateral direction, and the first pass-gate transistor of the first one of the second memory cells has a gate structure with a second length extending in the second lateral direction, and wherein the first length is shorter than the second length.

2. The memory circuit of claim 1, wherein the plurality of first memory cells and the plurality of second memory cells each include a dual-port static random access memory (DP SRAM) cell.

3. The memory device of claim 1, wherein the first bit line includes at least a first metal track extending in the first lateral direction, a second metal track extending in the second lateral direction, a third metal track extending in the first lateral direction, a fourth metal track extending in the second lateral direction, and a fifth metal track extending in the first lateral direction.

4. The memory device of claim 3, wherein the first and fifth metal tracks are disposed in a first metallization layer, the second and fourth metal tracks are disposed in a second metallization layer, and the third metal track is disposed in a third metallization layer.

5. The memory device of claim 4, wherein the third metallization layer is disposed over the second metallization layer, and the second metallization layer is disposed over the first metallization layer.

6. The memory device of claim 5, wherein the second to fourth metal tracks are interposed between the first memory array and the second memory array in the first lateral direction.

7. The memory circuit of claim 1, further comprising:
a second bit line operatively coupled at least to the second I/O circuit, a second pass-gate transistor of the first one of the second memory cells, and a second pass-gate transistor of the first one of the first memory cells;
wherein the second pass-gate transistor of the first one of the second memory cells has a gate structure with the first length extending in the second lateral direction, and the second pass-gate transistor of the first one of the first memory cells has a gate structure with the second length extending in the second lateral direction.

8. The memory circuit of claim 7, wherein the second bit line includes at least a first metal track extending in the first lateral direction, a second metal track extending in the second lateral direction, a third metal track extending in the first lateral direction, a fourth metal track extending in the second lateral direction, and fifth metal track extending in the first lateral direction, and wherein the first and fifth metal tracks are disposed in a first metallization layer, the second and fourth metal tracks are disposed in a second metallization layer over the first metallization layer, and the third metal track is disposed in a third metallization layer over the second metallization layer.

9. The memory circuit of claim 1, wherein the first I/O circuit and the second I/O circuit each include a sense amplifier.

10. The memory circuit of claim 1, wherein the first bit line is operatively coupled further to a first pass-gate transistor of a second one of the first memory cells, and a first pass-gate transistor of a second one of the second memory cells, and wherein the first pass-gate transistor of the second one of the first memory cells has a gate structure with the first length extending in the second lateral direction, and the first pass-gate transistor of the second one of the second memory cells has a gate structure with the second length extending in the second lateral direction.

11. The memory circuit of claim 10, wherein the first one and the second one of the first memory cell are physically located with respect to each other along the first lateral direction, and the first one and the second one of the second memory cells are physically located with respect to each other along the first lateral direction.

12. A memory circuit, comprising:
a first memory cell of a first memory array, the first memory cell comprising a first pass-gate transistor, a second pass-gate transistor, a third pass-gate transistor, and a fourth pass-gate transistor operatively coupled to a first bit line, a second bit line, a third bit line complement to the first bit line, and a fourth bit line complement to the second bit line, respectively; and
a second memory cell of a second memory array physically disposed with respect to the first memory array along a first lateral direction, the second memory cell comprising a fifth pass-gate transistor, a sixth pass-gate transistor, a seventh pass-gate transistor, and an eighth pass-gate transistor operatively coupled to the second bit line, the first bit line, the fourth bit line, and the third bit line, respectively;
wherein the first bit line, the second bit line, the third bit line, and the fourth bit line each include at least a first metal track extending in the first lateral direction, a second metal track extending in a second lateral direction perpendicular to the first lateral direction, a third metal track extending in the first lateral direction, a fourth metal track extending in the second lateral direction, and a fifth metal track extending in the first lateral direction, and wherein the first and fifth metal tracks are disposed in a first metallization layer, the second and fourth metal tracks are disposed in a second metallization layer, and the third metal track is disposed in a third metallization layer.

13. The memory circuit of claim 12, wherein the second metallization layer is disposed over the first metallization layer, and the third metallization layer is disposed over the second metallization layer.

14. The memory circuit of claim 12, wherein the first, third, fifth, and seventh pass-gate transistors each have a gate structure with a first length extending in the second lateral direction, and the second, fourth, sixth, and eighth pass-gate transistors each have a gate structure with a second length, and wherein the first length is shorter than the second length.

15. The memory circuit of claim 12, further comprising:
a first input/output (I/O) circuit physically located opposite the first memory array from the second memory array along the first lateral direction; and
a second I/O circuit physically located opposite the second memory array from the first memory array along the first lateral direction.

16. The memory circuit of claim 15, wherein the first I/O circuit is operatively coupled to the first pass-gate transistor and the sixth transistor through the first bit line, and to the third pass-gate transistor and the eighth pass-gate transistor through the third bit line.

17. The memory circuit of claim 15, wherein the second I/O circuit is operatively coupled to the fifth pass-gate transistor and the second pass-gate transistor through the second bit line, and to the seventh pass-gate transistor and the fourth pass-gate transistor through the fourth bit line.

18. The memory circuit of claim 15, wherein the first I/O circuit and the second I/O circuit each include a sense amplifier.

19. A method for fabricating memory devices, comprising:
forming, in a first area of a substrate, a first memory array comprising a plurality of first memory cells;
forming, in a second area of the substrate located next to the first area along a first lateral direction, a second memory array comprising a plurality of second memory cells;
forming, in a third area of the substrate located opposite the first memory array from the second memory array along the first lateral direction, a first input/output (I/O) circuit;
forming, in a fourth area located opposite the second memory array from the first memory array along the first lateral direction, a second I/O circuit;
forming a first bit line configured to operatively couple the first I/O circuit to a first pass-gate transistor of each of the first memory cells and to a first pass-gate transistor of each of the second memory cells; and
forming a second bit line configured to operatively couple the second I/O circuit to a second pass-gate transistor of each of the first memory cells and to a second pass-gate transistor of each of the second memory cells;
wherein the first pass-gate transistor of each of the first memory cells and the second pass-gate transistor of each of the second memory cells each have a gate structure with a first length extending in a second lateral direction perpendicular to the first lateral direction, and the second pass-gate transistor of each of the first memory cells and the first pass-gate transistor of each of the second memory cells each have a gate structure with a second length extending in the second lateral direction, and wherein the first length is shorter than the second length.

20. The method of claim 19, wherein
the step of forming a first bit line comprises:
forming a first metal track extending in the first lateral direction and in a first one of a plurality of metallization layers over the substrate;
forming a second metal track extending in the second lateral direction and in a second one of the plurality of metallization layers over the first metallization layer;
forming a third metal track extending in the first lateral direction and in a third one of the plurality of metallization layers over the second metallization layer;
forming a fourth metal track extending in the second lateral direction and in the second metallization layer; and
forming a fifth metal track extending in the first lateral direction and in the first metallization layer;
the step of forming a second bit line comprises:
forming a sixth metal track extending in the first lateral direction and in the first metallization layer;
forming a seventh metal track extending in the second lateral direction and in the second metallization layer;
forming an eighth metal track extending in the first lateral direction and in the third metallization layer;
forming a ninth metal track extending in the second lateral direction and in the second metallization layer; and
forming a tenth metal track extending in the first lateral direction and in the first metallization layer.
